(19) United States
(12) Patent Application Publication
(10) Pub. No.: US 2025/0201295 A1
(43) Pub. Date: Jun. 19, 2025

(54) ROWHAMMER MITIGATION FOR A MEMORY DIE

(71) Applicant: Rambus Inc., San Jose, CA (US)

(72) Inventors: Wendy Elsasser, Austin, TX (US); Taeksang Song, San Jose, CA (US); Steven C. Woo, Saratoga, CA (US)

(21) Appl. No.: 18/966,657

(22) Filed: Dec. 3, 2024

Related U.S. Application Data
(60) Provisional application No. 63/611,462, filed on Dec. 18, 2023.

(51) Int. Cl. G11C 11/4078; G11C 11/408; G11C 11/4091; G11C 29/52

(52) U.S. Cl. CPC G11C 11/4078; G11C 11/4087; G11C 11/4091; G11C 29/52

(57) ABSTRACT

Technologies for Rowhammer mitigation in a memory die are described. A dynamic random-access memory (DRAM) device includes a plurality of memory array tiles (MATs), each MAT comprising multiple rows and columns of memory cells. Each MAT of the plurality of MATs having a plurality of main wordlines (MWLs) and a plurality of sub-wordlines (SWLs). Each row in the respective MAT corresponds to a SWL and each column in the respective MAT corresponds to a bitline (BL). For an activate command received by the DRAM device, a set of intermediate MWLs is enabled and different SWLs are activated from each MWL of the set of intermediate MWLs such that the different SWLs in each MAT are varied. The varying SWLs across MATs can serve as a Rowhammer mitigation mechanism. The Rowhammer mitigation mechanism can be used in connection with an error detection mechanism to detect failures caused by a Rowhammer attack.

### RELATED APPLICATIONS

This application claims the benefit of U.S. Provisional Application No. 63/611,462, filed Dec. 18, 2023, the entire contents of which is incorporated herein by reference.

### BACKGROUND

Modern computer systems generally include a data storage device, such as a memory component or device. The memory component may be, for example, a random-access memory (RAM) or a dynamic random-access memory (DRAM) device. The memory device includes memory banks made up of memory cells that a memory controller or memory client accesses through a command interface and a data interface within the memory device. The memory devices can be located on a memory module. The memory module can include one or more volatile memory devices.

Rowhammer is a hardware vulnerability that affects DRAM devices, also called DRAM chips. By repeatedly accessing specific rows of the memory, an attacker can induce bit flips (i.e., changing a bit's value from 0 to 1 or vice versa) in adjacent rows, even if those rows are not being directly accessed. An attacker can potentially exploit these induced bit flips for malicious purposes. For example, they might be able to change the values in memory that grant permissions or alter program behavior in unintended ways, leading to security breaches.

### BRIEF DESCRIPTION OF THE DRAWINGS

The present disclosure is illustrated by way of example, and not by way of limitation, in the figures of the accompanying drawings.

FIG. 1 is a block diagram of a memory die with sub-wordline (SWL) drivers that vary wordlines selected per memory access tile (MAT) or set of MATs of a memory bank for Rowhammer mitigation according to at least one embodiment.

FIG. 2 is a block diagram of the memory bank of FIG. 1 with multiple memory access tiles (MATs) with sub-wordline (SWL) drivers and bitline sense amplifiers (BLSAs) according to at least one embodiment.

FIG. 3 is a block diagram of a portion of a memory bank with sixty-four blocks, each block having sixteen MATs according to at least one embodiment.

FIG. 4 is a block diagram of a memory bank with multiple MATs in which a set of main wordlines (MWLs) are enabled and SWLs selected per MAT or set of MATs according to at least one embodiment.

FIG. 5 is an encoding table illustrating five unique encodings of unique MWL addresses and a simple shift down and rotate function to change adjacent rows for most MATs according to at least one embodiment.

FIG. 6 is a block diagram of a portion of a block with multiple MAT-pairs, each MAT-pair having eight SWLs per each MWL according to at least one embodiment.

FIG. 7 is an encoding table with variable SWL encodings varying across eight SWLs per MWL according to at least one embodiment.

FIG. 8A illustrates MWL logic according to at least one embodiment.

FIG. 8B illustrates SWL logic according to at least one embodiment.

FIG. 8C illustrates sense amplifier (SA) control logic according to at least one embodiment.

FIG. 9 is a block diagram of a portion of a memory array with sets of rows enabled across blocks according to at least one embodiment.

FIG. 10 is an encoding table illustrating five unique encodings of unique MWL addresses across blocks and a simple shift down and rotate function to change adjacent rows for most MATs according to at least one embodiment.

FIG. 11 illustrates decoding different SWL encodings every two MATs according to at least one embodiment.

FIG. 12 illustrates decoding different SWL encodings every two MATs with multiple blocks according to at least one embodiment.

FIG. 13 illustrates a method for Rowhammer mitigation according to at least one embodiment.

### DETAILED DESCRIPTION

Technologies for Rowhammer mitigation in a memory die are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, in a Rowhammer attack, an attacker repeatedly accesses (or “hammers”) specific rows in a DRAM device. Aggressively activating certain memory rows can cause capacitors in nearby rows to either gain or lose their charge. Due to the aggressive access of certain rows and the unintended interactions between memory cells, adjacent rows might experience bit flips. This means a bit that was set to 0 might change to 1 or vice versa. An attacker can potentially exploit these induced bit flips for malicious purposes. For example, they might be able to change the values in memory that grant permissions or alter program behavior in unintended ways, leading to security breaches. Rowhammer is an issue for all DRAM, including high-bandwidth memory (HBM), low power double data rate (LPDDR), and DDRx.

Error correcting code (ECC) codewords (e.g., data and parity) have limited capability to detect and correct errors. For example, in a case of a Reed-Solomon (RS) error-correcting code using a Galois Field (GF) of size 2\hat{ }16 (RS (20,16) GF (2¹⁶), the ECC engine can correct up to two symbol errors. If an aggressor can induce bit-flips of all symbols within a victim codeword (e.g., all 20 symbols in RS (20,16)), then the ECC engine cannot detect and correct the symbol errors.

Aspects and embodiments of the present disclosure address Rowhammer vulnerability and other deficiencies by optimizing a row-address decoder (main wordline (MWL) and wordline (WL) drivers/decoders to vary victim rows across MATs such that an aggressor can only induce bit-flips of a portion of symbols within a victim codeword (e.g., only one or two symbols in the twenty symbols in RS (20,16). Aspects and embodiments of the present disclosure provide logic to vary selected WLs across MATs so that the adjacent rows vary across the MATs. The logic can select SWLs such that each MAT has different encoded adjacent row address than other MATs, or at least most MATs have different encoded adjacent row addresses), as described in more detail below. A MAT is a sub-array tile within a memory die and includes multiple rows and columns of memory cells (e.g., 512 row×512 columns). Each row in a MAT corresponds to a wordline, and each column to a bitline. When a specific memory location is accessed, the relevant MATs are activated, and the specified rows and columns are selected, and data is fetched from the specified row and column. A single memory die can include one or more banks with one or more blocks, where each block includes multiple MATs (or subarrays), each MAT having rows and columns corresponding to memory cells, as described in more detail below.

Aspects and embodiments of the present disclosure, by varying wordlines across the MATs, can bound errors that would be seen by a host controller (also referred to herein as a “host” or a “controller”), caused by Rowhammer faults, to a limited number of bits that potentially would be in error. The aspects and embodiments described herein vary the encoding of the wordlines that are selected across the MATs (i.e., activates different wordlines across the MATs). Here, each MAT can have a different wordline addresses, causing each MAT to have different adjacent row encodings. That is, there are physically different SWLs driven across the mats because of the different adjacent row encodings. For example, without modifying row decoding with row address variations (also referred to as “row address swizzling” or “row address scrambling”), a read operation of a host address could cause the SWL drivers to select different MWL addresses from a set of enabled MWLs, but all of the victims rows of the selected WLs would be accessed simultaneously with the same host address (e.g. four MWLs enabled out of 128 with a consistent static spacing of 32). To bound the errors, in addition to using different addresses across MATs, different MWLs could be selected across the MATs. By modifying the row decoding, a read operation of a host address would cause multiple SWL drivers to select different wordline addresses across the MAT or set of MATs. So, when a host does a read operation and the attacker is successful in a flipping bits with a Rowhammer attack, the read data that would flip as a result of the Rowhammer attack would be within data received from a single MAT (or a subset of MATs as described herein). Because it is limited to one MAT, the flipped data would be less than a full burst (i.e., the flipped data is contained within 16 bits, instead of 64 bytes (or 512 bits) returned to the host). Even though each MAT across the DRAM could be exposed to the Rowhammer attack, because the addresses are varied across the MATs, the host will only see bit flips caused by the Rowhammer in a limited number of bits being read (i.e., bits from one MAT). As described herein, the internal DRAM includes row decoding with row address variations (also referred to as “row address swizzling” or “row address scrambling”). The variations or re-mappings at the MAT level (or set of MATs level) are not random (as suggested by scrambling), but are deterministic, such as algorithmically for Rowhammer mitigation. The physical address is uniquely remapped at a MAT level to change victim rows across the MATs. In a first decode stage, the row decoding can enable a set of MWLs within a block (or across blocks) and the address bits can be varied (“swizzled”) for unique encodings across the MATs. In a second decode stage, the row decoding can use one MWL for a subset of MATs that are enabled by the set of MWLs. The row decoding can select one MWL for each subset of MATs. The row address variations (“row address swizzling”) in the first decode stage generates different victim rows in the different MATs, bounding the errors to one of the MATs. Although the row address variations can vary in a lock-step manner across the MATs, the row address variations could have other systematic variations, where most or all of the MATs have different adjacent rows for a selected row. Since a set of MWLs are enabled in the first decode stage, the second decode stage can select one of the MWLs within the MAT so that the data provided to the BLSAs within a MAT is appropriate for the page size, and a single SWL is driven within the MAT (i.e., two cells are not selected).

A second aspect in protecting against Rowhammer attacks is the ability to recover data that has been flipped. There are various techniques to recover data, and these techniques have tradeoffs between bitflip protections versus overhead needed to recover data. By binding the errors seen by the host to one MAT, these recovery techniques can be used to recover data that has flipped caused by a Rowhammer attack. In some embodiments, error detection and correction mechanisms for reliability availability serviceability (RAS) can be located on-die or on the host to detect and correct errors in the data. For example, error correcting code (ECC) memory can be used for 32-bit correction of errors (e.g., a specific configuration of a Reed-Solomon (RS) error-correcting code using a Galois Field (GF) of size 2\hat{ }16 (RS (20,16) GF (2¹⁶)). The row address swizzling can be used in connection with an error detection mechanism. The error detection mechanism, such as a symbol-based error detection mechanism, can be used to detect failures/errors caused by a Rowhammer attack. In particular, the error detection mechanism can detect a failure in a portion of read data or write data corresponding to the activated MATs.

Aspects and embodiments of the present disclosure can bound Rowhammer faults within a DRAM page (or row buffer). The Rowhammer faults can be bound within a portion of symbols in a codeword. Aspects and embodiments of the present disclosure can limit the number of bits per read that have flipped due to Rowhammer. Aspects and embodiments of the present disclosure can provide a solution in which a host physical row internally translates to multiple DRAM physical rows across the MATs. In particular, the host physical row translates to a different main wordline (MWL) address per MAT, varying the MWLs across the MATs. As a result, an aggressor row address varies across DRAM MATs, affecting different victim rows across the MATs. In some implementations, SWL drivers can select different main wordlines (MWLs) for a subset of MATs, bounding the errors. The different MATs enabled across different physical rows can create a full logical page. In other implementations, variations in sub-wordline (SWL) decoding can be incorporated. Also, variations between the dies of a 3D-stacked packaging (3DS) can be incorporated across the 3DS stack. The decoding can be hard-coded or programmable. In a 3D-stacked packaging approach, the semiconductor dies are stacked on top of each other in a vertical orientation. Interconnects between die may be made using Through-Silicon Vias (TSVs).

It should be noted that aspects and embodiments of the present disclosure describe Rowhammer mitigation within a die. In other embodiments, the Rowhammer mitigation described herein can be extended to multi-die packages.

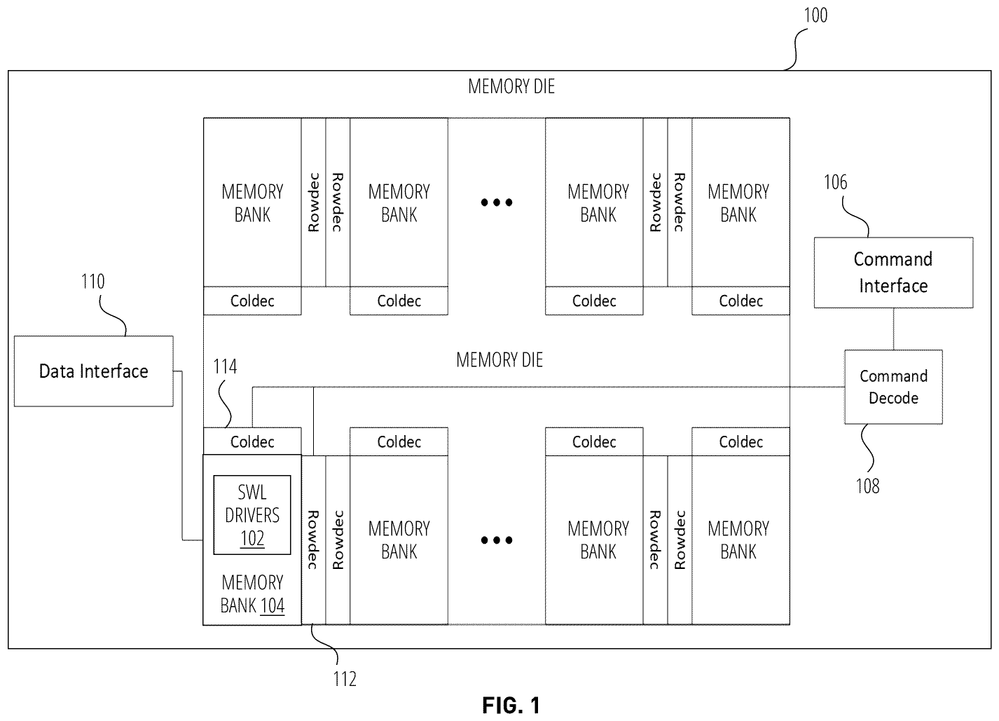

FIG. 1 is a block diagram of a single memory die 100 with SWL drivers 102 that vary wordlines selected per MAT or set of MATs of a memory bank for Rowhammer mitigation according to at least one embodiment. The memory die 100 includes one or more banks with one or more blocks, where each block includes multiple MATs (or subarrays), each MAT having rows, columns, per-SWL driver corresponding to memory cells. Each memory bank as illustrated in FIG. 1 could be a full bank or a portion of a bank. The memory die 100 also includes a command interface 106, a data interface 110, and a command decode block 108. The command decode block 108 can receive a command from a host through the command interface 106. The command can be read or write commands. The read data can be read from the corresponding memory bank and provided on the data interface 110. Write data can be received from the data interface 110 and written to the corresponding memory bank. The command can include an address (e.g., physical address) to identify which memory bank to access, as well as which MATs within the memory bank to access. The command decode block 108 can access a particular memory bank using row decoders and column decoders. Each memory bank can include multiple blocks, where each block includes multiple MATs. Each MAT can be a subset of wordlines and bitlines coupled to SWL drivers 102 and bitline sense amplifiers (BLSAs). The MAT can be a repeatable sub-array memory tile, where a block can include multiple MATs and multiple blocks make up the memory bank.

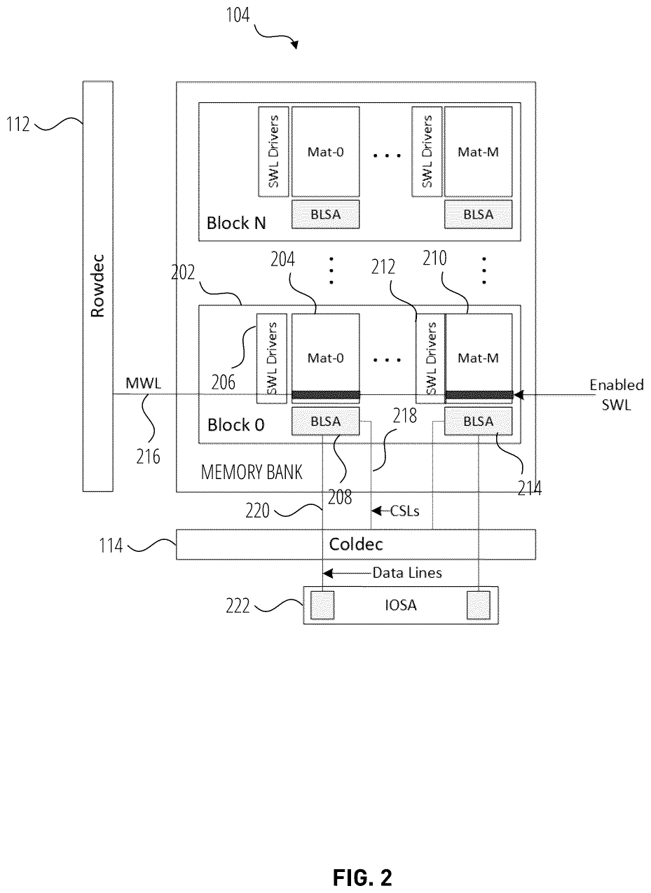

As illustrated in FIG. 1, the command decode block 108 is coupled to a row decoder 112 and a column decoder 114 for a memory bank 104. The other memory banks of the memory die 100 have similar row and column decoders and are similarly connected to the command decode block 108 and data interface 110. The command decode block 108 can receive a command, and corresponding address, from a host to read or write data from the memory bank 104. The command decode block 108, row decoder 112, and column decoder 114 can perform two decode stages to identify the memory bank 104. During a first decode stage, the row decoder 112 enables a set of MWLs within a block (or across multiple blocks) and the address bits can be varied (“swizzled”) for unique encodings at each MAT. During a second decode stage, the SWL drivers 102 can select a unique SWL for each MAT. The row address variations (“row address swizzling”) in the first decode stage cause different victim rows in the different MATs. That is, each MAT has different adjacent rows to its selected row than the other MATs. As described herein, the SWL drivers 102 can be used to enable a subset of MATs (e.g., 4 MATs) of a block using one or more MWLs and select one SWL per MAT, where each row address selected in a given MAT has different adjacent rows than other MATs as described herein. The row address variations across the MATs are described in more detail below with respect to FIG. 2, which illustrates additional details of the memory bank 104. It should be noted that not all components of the single memory die 100 are illustrated. For example, refresh control is not depicted. Also, the block diagram shows connections to a single memory bank, memory bank 104, though the command interface 106 and the data interface 110 are similarly connected to other memory banks.

In at least one embodiment, a memory die includes one or more blocks having a plurality of MATs. Each MAT includes a set of MWLs (e.g., 128 MWLs) and a set of SWLs (also referred to here as wordlines or WLs) for each MWL (e.g., 1024 WLs with 8 per MWL). The die can include decoding logic that receives an address associated with a command that specifies an access operation. The decoding logic decodes the address in a first decode stage and a second decode stage. In the first decode stage, the decoding logic can enable a set of MWLs. In a second decode stage, the decoding logic can select one MWL of the set of MWLs to drive an SWL in each MAT. At least one of the one MWL or the SWL address in a first MAT of the plurality of MATs varies from at least one of the one MWL or the SWL address in a second MAT of the plurality of MATs. Varying the SWLs across the plurality of MATs can be used as a Rowhammer mitigation mechanisms.

In at least one embodiment, the plurality of MATs is part of a first block of the one or more blocks. In at least one embodiment, the first MAT is part of a first block of the one or more blocks, and the second MAT is part of a second block of the one or more blocks. That is, the MWLs and/or SWLs of the MATs can be varied across blocks.

In at least one embodiment, the first MAT has a first set of MWL addresses that vary from a second set of MWL addresses of the second MAT. In at least one embodiment, the first MAT has a first set of SWL addresses that vary from a second set of SWL addresses of the second MAT.

In at least one embodiment, a DRAM device includes a command interface and a plurality of MATs. Each MAT includes multiple rows and columns of memory cells. Each MAT of the plurality of MATs has a plurality of MWLs and a plurality of SWLs. Each row in the respective MAT corresponds to a SWL and each column in the respective MAT corresponds to a bitline (BL). The command interface can receive an activate command, such as from a host. For the activate command received by the command interface, a set of intermediate MWLs is enabled and different SWLs are activated for each MWL of the set of intermediate MWLs such that a different SWL address is selected in each MAT (or a set of MATs) to vary the possible victim rows across the block or blocks. In at least one embodiment, the different SWLs in each MAT being varied is a Rowhammer mitigation mechanism that limits a number of bits per read flipped due to a Rowhammer attack. In at least one embodiment, the DRAM device includes an error detection mechanism to detect failures in the DRAM device.

In at least one embodiment, the DRAM device is a stacked device with multiple die. The different SWLs activated are spread across different die in in the stacked device.

In at least one embodiment, a physical row address, received from a host, translates to a different SWL per MAT such that an aggressor row affects different victim rows across the plurality of MATs. In at least one embodiment, the different SWLs in each MAT being varied limits a number of bits flipped per read operation due to one or more errors in one or a set of MATs of the plurality of MATs.

In at least one embodiment, the DRAM device further includes a row decoder (e.g., row decoder 112) a column decoder (e.g., column decoder 114). The column decoder 114 can be used to move a subset of the row buffer (the prefetch) to the input-output sense amplifiers (IOSA). This would occur based on a read/write command. The row decoder 112 includes logic to drive the MWL and SWL driver logic to select a specific WL based on MWL assertion and SWL addressing as described herein. The selection of the MWL and SWL occurs within the activate command and moves the data from the bit cells to the bitline sense amplifiers (BLSA). The DRAM device includes a memory bank coupled to the row decoder and the column decoder. The memory bank includes a plurality of blocks. A first block of the plurality of blocks includes the plurality of MATs. In another embodiment, the plurality of MATs is spread across multiple blocks. The DRAM device further includes SWL drivers and BLSAs. In response to the activate command, the row decoder can assert the set of intermediate MWLs in the first block, and the SWL drivers can activate the different SWLs, one SWL per MAT or per MAT-pair. The different SWLs in each MAT or MAT-pair are varied.

In at least one embodiment, the DRAM device further includes a memory bank with the plurality of MATs. The DRAM device includes MWL drivers and SWL drivers coupled to the plurality of MATs. The DRAM device includes SA control logic coupled to the BLSA of the plurality of MATs. The SA control logic can be used to selectively enable or disable the BLSA logic. The SA logic can be enabled or disabled based on the enablement of the SWL drivers. As one example, different MATs can be enabled across different blocks with a subset of the page coming from each block. Thus, a subset of the BLSAs would be enabled. The MWL drivers can perform a first decode operation to enable a set of a number of MWLs. The SA control logic and SWL drivers can perform a second decode operation to select one of the MWLs enabled to drive one SWL per MAT.

In at least one embodiment, the plurality of MATs are located in a first block of a plurality of blocks in the memory bank. In at least one embodiment, the plurality of MATs are located across multiple blocks of the memory bank.

In at least one embodiment, the DRAM device includes command and address (CA) logic that can encode each MAT of the plurality of MATs with a set of unique MWL addresses that vary across the plurality of MATs. In at least one embodiment, the CA logic can encode each MAT of the plurality of MATs with a set of unique SWL addresses that vary across the plurality of MATs. In at least one embodiment, the CA logic can encode each MAT with the set of unique MWL address and the set of unique SWL addresses. In at least one embodiment, the CA logic can encode a first MAT of the plurality of MATs with a first set of MWL addresses, and encode a second MAT of the plurality of MATs with a second set of MWL address, the second set being different than the first set.

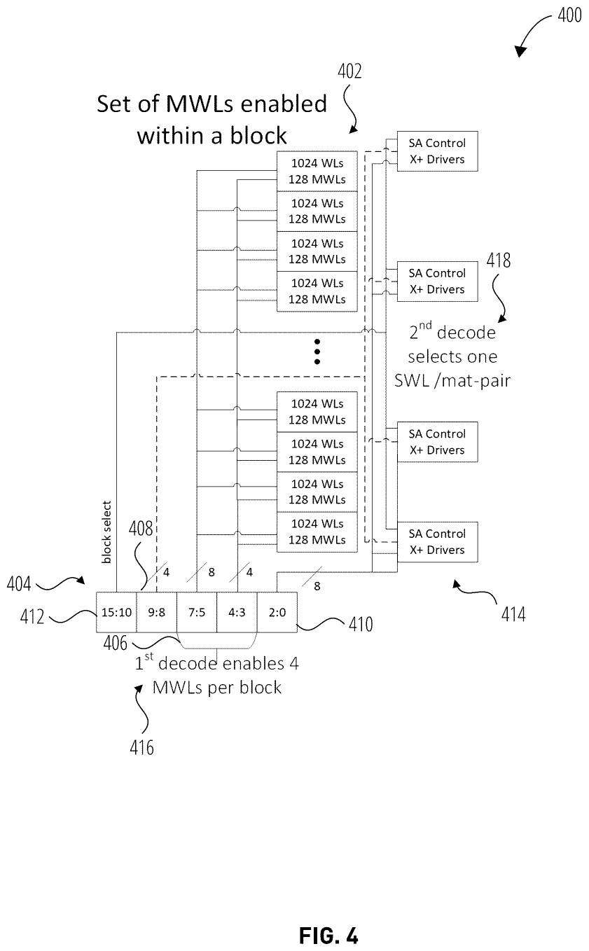

FIG. 2 is a block diagram of the memory bank 104 of FIG. 1 with multiple MATs with sub-wordline drivers (SWL drivers) 206 and BLSA 208 according to at least one embodiment. The SWL drivers 206 can be similar to the SWL drivers 102 described above with respect to FIG. 1. As illustrated in FIG. 2, the memory bank 104 includes multiple blocks, block 0 to block N, where N is a positive integer of one or greater. A first block 202 (labeled Block-0) can include multiple MATs, MAT 0 to MAT M, where M is a positive integer of one or greater. A first MAT 204 (labeled Mat-0) has a set of memory cells that are coupled to SWL drivers 206 and BLSAs 208. The SWL drivers 206 are coupled to the row decoder 112 via MWL 216. The SWL drivers 206 can be coupled to the row decoder 112 via multiple MWLs. The BLSAs 208 are coupled to input-output sense amplifiers (IOSA) 222 via data lines 220. The BLSAs 208 are also coupled to the column decoder 114 via column select lines (CSLs) 218. It should be noted that the block diagram only shows connections to the first block 202 (Block-0), but there are MWLs and CSLs routed to all blocks. Also, data lines are routed between the IOSA 222 and the BLSAs of all blocks. As described herein, multiple MATs can be enabled by the MWL 216 and the SWL drivers 206 can select a SWL per each MAT, where each MAT has unique address encodings that result in different adjacent rows for the selected SWL across the multiple MATs. In particular, the host physical row in the address translates to different SWLs per MAT. An aggressor row address varies across the MATs, affecting different victim rows. This bounds faults caused by Rowhammer attacks to one or more MATs depending on the implementation (e.g., 16 or 32-bits, respectively). Also, the row decoding can enable a set of MWLs with the block 202 (or across blocks), and the address bits are swizzled for unique address encodings at each MAT. One MWL 216 can be used for a subset of MATs. The SWL drivers 206 can select one SWL for each set of MATs. The swizzling in the first decode stage generates different victim rows, bounding the errors to the one MAT (or set of MATs). The variations in the row decoding are described in more detail below with respect to FIG. 4.

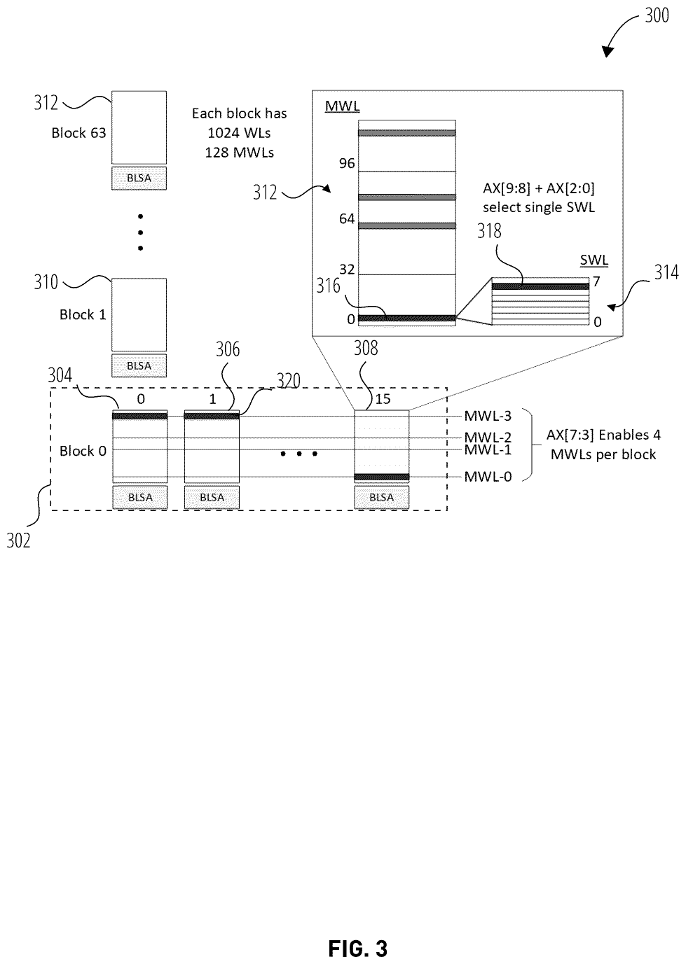

FIG. 3 is a block diagram of a portion of a memory bank 300 with sixty-four blocks, each block having sixteen MATs according to at least one embodiment. Although the sixteen MATs of a first block 302 are shown, the other sixty-three blocks would have a similar number of MATs even though a MAT 310 for a second block and a MAT MWLs 312 for a sixty-fourth block are illustrated. The first block 302 includes sixteen MATs, even though a first MAT 304, a second MAT 306, and a sixteenth MAT 308 are illustrated. In an expanded view of the sixteenth MAT 308, there are 128 MWLs 312 and, for each MWL 312, there are eight SWLs 314. As illustrated in FIG. 3, a first portion of an address (e.g., AX[7:3]) enables four MWLs 312 per block (i.e., the first block 302 as illustrated). The first portion can be swizzled (i.e., varied) across MWL drivers (e.g., different encoding every 32 MWLs). That is, the MWL driver circuit can include swizzling logic to select four unique MWLs with different neighbors. For each MAT, one of the four MWLs 312 is selected. As illustrated, a first MWL 316 is enabled for the sixteenth MAT 308. A second portion of the address (e.g., AX[9:8]) can be varied (i.e., swizzled) across MATs. For example, a fourth MWL 320 is enabled for the first MAT 304 and the second MAT 306. A second MWL and a third MWL can be enabled for other MATs in the first block 302 (not illustrated in FIG. 3). A third portion of the address (e.g., AX[2:0]) can be combined with the second portion (e.g., AX[9:8]) to select a unique SWL per MAT. As illustrated in FIG. 3, the second portion and the third portion select a seventh SWL 318 for the sixteenth MAT 308. Different SWLs can be selected within the other MATs of the first block 302.

In this example, each block has 1024 WLs (i.e., SWLs) and 128 MWLs. The address can be 16 bits in this example, but can include other number of bits. The lower bits of the 16-bit address can be used to select SWL drivers (X+ drivers)). The upper bits of the 16-bit address can be used to select the block. The middle bits of the 16-bit address can be used to select the MWLs. The middle and lower bits can be combined to select the SWL drivers, ensuring that only one MWL driver is enabled from the set of MWL drivers enabled by the middle bits. The MWLs and SWLs can be enabled as a result of two decoding stages, such as illustrated in FIG. 4.

FIG. 4 is a block diagram of a memory bank 400 with multiple blocks in which a set of MWLs are enabled and SWLs selected per MAT or set of MATs (e.g., 2 MATs) according to at least one embodiment. The memory bank 400 includes multiple blocks 402, each block including 1024 WLs (i.e., SWLs) and 128 MWLs. Each block 402 and corresponding SA control and SWL drivers 414 illustrate the logic required per block for row decode (i.e., assert a MWL and then select the right SWL in the right block. An address 404 can be used to select the block 402, enabling the corresponding SA control and SWL drivers 414. As described above, a first portion 406 (e.g., AX[7:3]) of an address 404 can be decoded to enable four MWLs per block. The first portion 406 can be swizzled or varied across MWL drivers (e.g., different encoding every 32 MWLs). For example, as illustrated in FIG. 3, the first portion 406 can select the first MWL 316, a second MWL, a third MWL, and a fourth MWL 320. A second portion 408 of the address 404 (e.g., AX[9:8]) can be varied (i.e., swizzled) across MATs. The second portion can be used by the SWL drivers to enable only one MWL per MAT. For example, as illustrated in FIG. 3, the first MWL 316 is enabled for the sixteenth MAT 308 and the fourth MWL 320 is enabled for the first MAT 304 and the second MAT 306. A third portion 410 of the address 404 (e.g., AX[2:0]) can be combined with the second portion 408 (e.g., AX[9:8]) to select a unique SWL per MAT. For example, as illustrated in FIG. 3, the second portion 408 and the third portion 410 can select the seventh SWL 318 for the sixteenth MAT 308. Different SWLs can be selected within the other MATs of the memory bank 400. Also, a fourth portion 412 (e.g., AX15:10) of the address 404 can be used to select the memory bank 400.

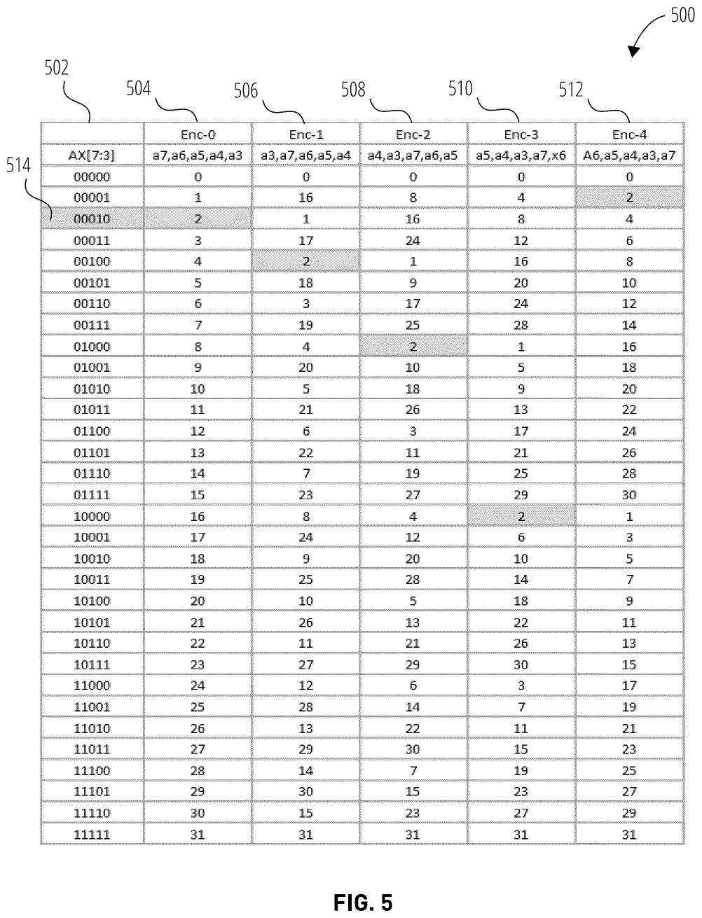

As described herein, the set of four MWLs can be enabled as a result of a first decode stage 416 using MWL drivers (not illustrated in FIG. 4). The one MWL of the set of four MWLs can be enabled and a unique SWL can be selected per a set of MATs (e.g., 1 to N, where N is a positive integer) as a result of a second decode stage 418 using SA control and SWL drivers 414. The MATs can be organized as a set of mats (i.e., two MATs). Alternatively, the unique SWL can be enabled for each MAT. The SWL can be selected for each MAT, further limiting the impact of a Rowhammer attack (e.g, 16-bit error boundary when each MAT contributes 16-bits to a data burst). The SA control can control the BLSAs for the given MAT. The SWL drivers can use the second portion 408 and the third portion 410 to select one SWL for one of the MWLs from the set of four MWLs for the respective MAT. It should be noted that in other embodiments, a block can have different numbers of MATs, WLs, MWLs, MWL drivers, and SA control and SWL drivers. As such, the portions of the address to be decoded for enabling a set of MWLs and enabling one MWL from the set and selecting the SWLs can be different numbers of bits. In this embodiment, there can be five unique encodings possible using the first portion 406 (e.g., AX[7:3]) of the address 404. These five unique encodings can be used to select unique MWL addresses across the MATs. The row address swizzling can change adjacent rows for most or all of the MATs, using a row varying technique, such as a simple shift down and rotate function, as illustrated in an encoding table of FIG. 5.

FIG. 5 is an encoding table 500 illustrating five unique encodings of MWL addresses and a simple shift down and rotate function to change adjacent rows for most MATs according to at least one embodiment. As describe above, a first portion of an address, referred to as a MWL address 502, can be varied across MWL drivers according to five different unique encodings 504-512. The unique encodings 504-512 can be considered another layer of address translation, but the address is varied across MATs in a block or across blocks.

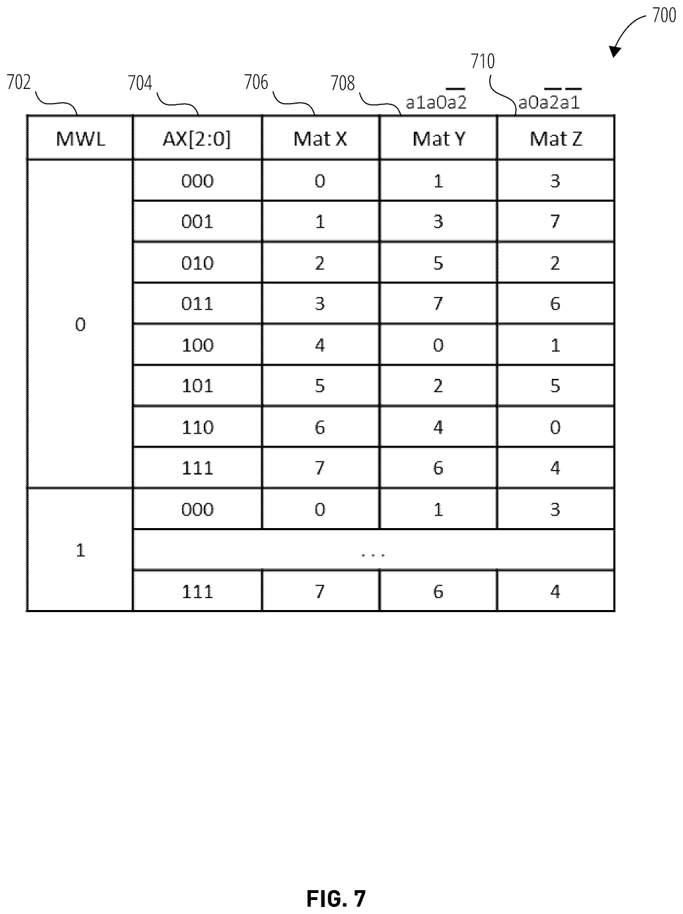

In the illustrated example of the encoding table 500, the row addresses are varied using a simple shift down and rotate function. For example, a first MWL address of 00010 can select a third row (r2) for a first encoding 504, a second row (r1) for a second encoding 506, a seventeenth row (r16) for a third encoding 508, a ninth row (r8) for a fourth encoding 510, and a fifth row (r4) for a fifth encoding 512. More importantly, the varying technique changes the adjacent row encodings across the MATs, where the different encodings can correspond to different MATs. For example, the encoded adjacent rows for the third row (r2) vary across the different encodings 504-512. In particular, the encoded adjacent rows of a third row (r2) are rows (r1, r3) for the first encoding 504, rows (r17, r18) for the second encoding 506, rows (r10, r25) for the third encoding 508, rows (r6, r29) for the fourth encoding 510, and rows (r0, r4) for the fifth encoding 512. In some cases, the encoding table 500 is known only to the DRAM. In other embodiments, the encoding table 500 can be provided to a host (e.g., mode registers or the like). The host could use the encoding table 500 to improve error detection and correction. The encoding table 500 shows the varying row addresses at a MAT level, but the encodings could be done at a set of MAT levels. However, varying the row addresses at the MAT level can help bound Rowhammer errors to a size that an ECC mechanism can more easily detect and correct the errors than at a block level, for example. Although the varying technique illustrated in FIG. 5 is a simple shift down and rotate function, in other embodiments, other varying techniques (methods or functions) can be used to varying the MWLs across the multiple MATs according to unique encodings. As described herein, the SWL encoding can also vary across the SWLs per each MWL, called “SWL swizzling”, as illustrated in FIG. 7.

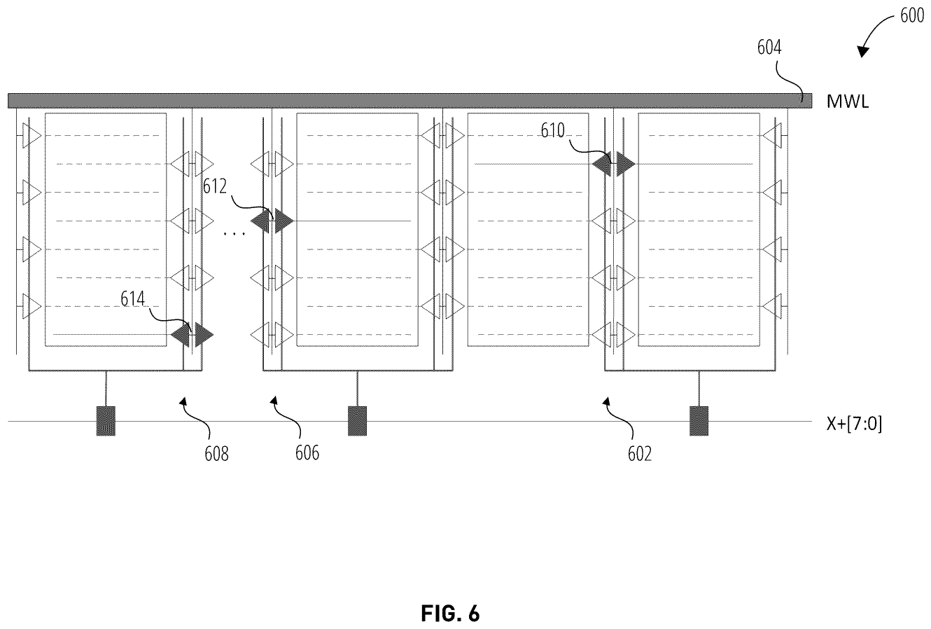

FIG. 6 is a block diagram of a portion of a block 600 with multiple MAT-pairs, each MAT-pair having eight SWLs per each MWL according to at least one embodiment. The block 600 includes a first MAT-pair 602 coupled to a MWL 604 and having eight SWLs shared between two MATs. The block 600 includes a second MAT-pair 606 coupled to the MWL 604 and having eight SWLs shared between two MATs (only one MAT of the second MAT-pair 606 is illustrated in FIG. 6). The DRAM can be architected two MATs per SWL driver (e.g., eight SWL drivers are split between two MATs, a MAT-pair). The block 600 includes a Nth MAT-pair 608 coupled to the MWL 604 and having eight SWLs shared between two MATs (only one MAT of the Nth MAT-pair 608 is illustrated in FIG. 6). As described herein the SWL encodings can vary across the eight SWLs per MWL. When the MWL 604 is selected, different SWLs can be selected for different MAT-pairs. For example, a first SWL 610 is selected for the first MAT-pair 602, a second SWL 612 is selected for the second MAT-pair 606, and a third SWL 614 is selected for the Nth MAT-pair 608. The first SWL 610, second SWL 612, and third SWL 614 are different SWLs. As such, the encoded adjacent rows to the selected SWLs are different across the MAT-pairs. There can be different per-MAT wiring every MAT-pair. The portion of the address can be three bits, as one example, to provide three unique encodings. These three bits can be combined with the four MWLs up to fifteen combinations (e.g., 5×3=15 combinations for five unique encodings for the MWLs and three unique encodings for the SWLs). These different encodings can cover data MAT-pairs, as well as ECC data and redundancy data. In this embodiment, the errors can be a Rowhammer can be bound to one MAT-pair (i.e., two MATs). The row address swizzling for SWLs can change adjacent rows according to variable SWL encodings, such as illustrated in an encoding table of FIG. 7.

FIG. 7 is an encoding table with variable SWL encodings varying across eight SWLs per MWL according to at least one embodiment. As describe above, the third portion of the address, referred to as the X+ address (SWL address), used by the SA control and per-SWL drivers 414, can be varied across the MATs according to three unique encodings 706-710, referred to as SWL swizzling. In the illustrated example of the encoding table 700, the X+ address 704 is varied using a row varying technique. The SWL swizzling changes adjacent row encodings. For example, the encoded adjacent rows of a third row (r2) are rows (r1, r3) for a first encoding 706 (labeled Mat X), rows (r0, r4) for a second encoding 708 (labeled Mat Y), and rows (r6, r7) for a third encoding 710 (labeled Mat Z). The unique encodings 706-710 can be used for a first MWL address 702 and reused for each of the MWL addresses.

In another embodiment, the MWL boundaries can also be uniquely encoded. For example, the encoded adjacent rows of an eighth row (r7), which is a MWL boundary, can be encoded as rows (r0_next,r6) for the first encoding 706 (labeled Mat X), rows (r0_curr, r5) for the second encoding 708 (labeled Mat Y), and rows (r2, r3) for the third encoding 710 (labeled Mat Z).

As described herein, MWL logic in a first decode stage can select a set of MWLs per block. For example, four MWLs can be enabled using a first portion of an address (e.g., AX[7:3]). There can be one MWL per 32 (e.g., 1 in 0-31, 1 in 32-63, . . . , and so forth). It should also be noted that the decode in the first decode stage can swizzle the address bits to encode different MWLs with different encoded victim rows. SWL logic in a second decode stage can use a second portion (e.g., AX[9:8]) to enable only one MWL of the set per MAT. The SWL logic can use the second portion to selectively disable X+ signals (SWL signals) so that only one MWL drives a selected SWL. The second portion is swizzled across the MATs. An example of one-hot encodings plus the upper bits enables a X+ signal for one MWL per MAT, such illustrated in the following example, where s3s2s1s0 represents four wires including a one-hot encoding:
AX[9:8]=0
Mat0/1:s3s2s1s0→0001
Mat2/3:s2s1s0s3→0010
Mat4/5:s1s0s3s2→0100
Mat6/7:s0s3s2s1→1000

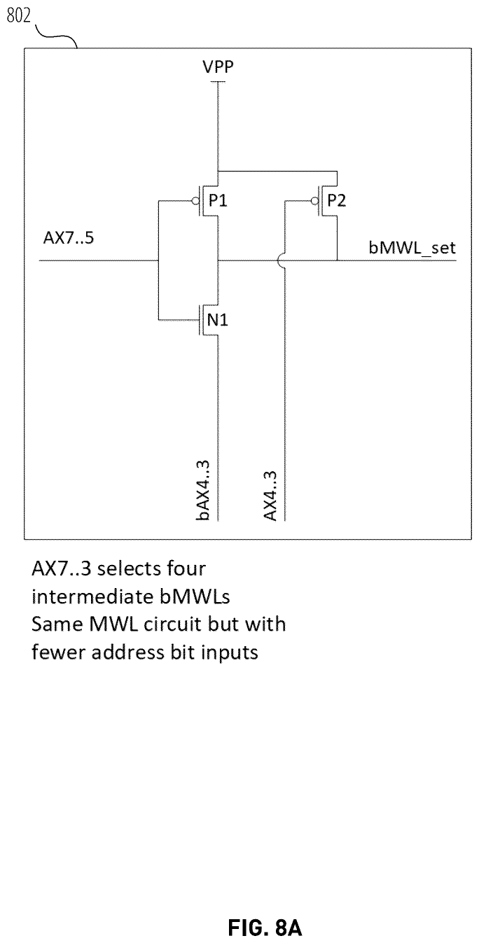

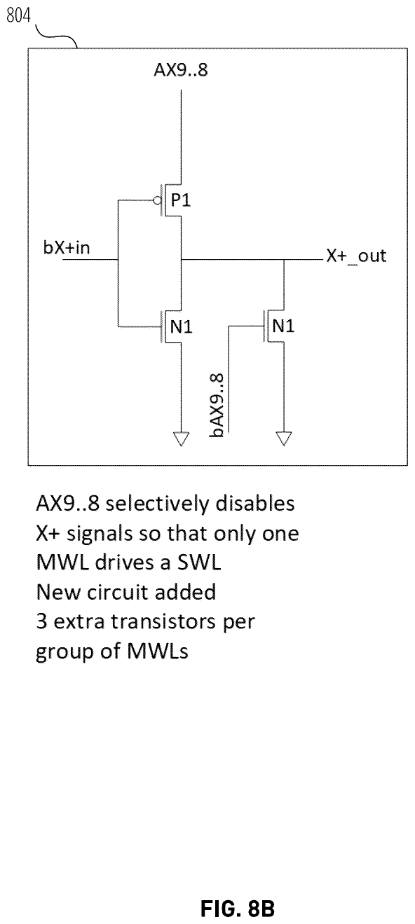

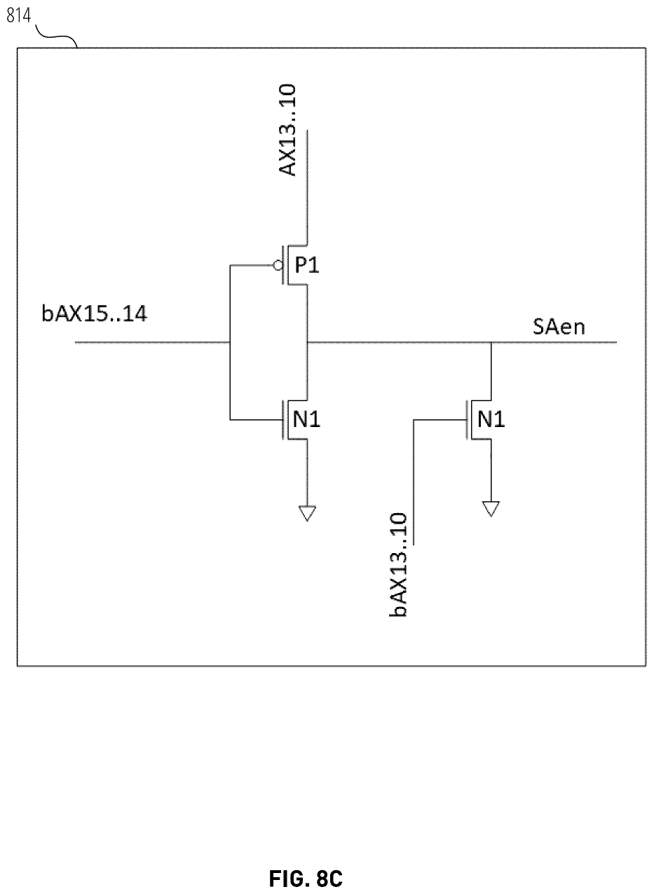

In at least one embodiment, three additional transistors are added per X+ and bX+ (active low version of X+, which is a one-hot encoding of the lower address bits) to enable only one of the MWLs selected by the MWL logic, such as illustrated in FIG. 8A and FIG. 8B.

FIG. 8A illustrates MWL logic 802 according to at least one embodiment. The MWL logic 802 includes three transistors to select a set of intermediate MWLs (e.g., four) using a first portion (e.g., AX[7:3]) of an address. The MWL logic 802 can be similar to prior MWL logic, except the MWL logic 802 includes fewer address bit inputs since some of the upper bits will be used with the SWL logic 804 of FIG. 8B. The MWL logic 802 can be used for all MWLs. When the MWL logic 802 receives the portion of the address at its input bits, multiple MWLs (e.g., a set of four, a set of eight, or the like) are enabled by the respective MWL logic 802.

FIG. 8B illustrates SWL logic 804 according to at least one embodiment. The SWL logic 804 includes three transistors to selectively disable X+ signals so that only one MWL of the set of enabled MWLs drives a SWL. The SWL logic 804 can be used for each SWL. The upper bits of the address and the lower bits corresponding to the SWL drivers can enable only one of the set of MWLs enabled by the MWL logic 802. The SWL logic 804 specifically uses the one-hot encodings of the three lower bits in combination with the upper bits to selectively disable SWLs, leaving only one of the set of enabled MWLs to drive one SWL. The SWL logic 804 can be a new circuit added to enable row address swizzling. Thus, as described above, three additional transistors are added per X+ and bX+. In one particular example, with three additional transistors per circuit for both X+ and bX (each an 8-bit one-hot) results in 48 total transistors (e.g., 3*(8+8)=48). Assuming 4 MWL enabled per block, the logic needed every 256 WLs (e.g., 1024/4=256), there are 192 total transistors per stripe (e.g., 48*4=192). A stripe, more specifically the row strip is the area between the MATs that are used for the SWL drivers. There are three transistors in the SWL logic. There can be 1024 SWL drivers split between two stripes (MAT-pairs), resulting in 1536 transistors per stripe (e.g., 3*1024/2=1536). This would result in 12.5% (e.g., 192/1536) increase in transistors per WL stripe using the MWL logic 802 and SWL logic 804 to enable a MWL with varied addresses across the MATs. This is a reasonable increase in die area to provide Rowhammer mitigation at a memory die level.

In another embodiment, the MWLs can be enabled in multiple blocks (e.g., 4). For example, a MWL can be enabled in every 16th block (e.g., blocks 0, 16, 32, 48) when there are 64 blocks. In this embodiment, the bitline sense amplifiers can be activated for a subset of each block. For example, the upper bits of a row address can be used (e.g., AX[15:14]) to enable the bitline sense amplifiers.

In some embodiments, the SWL driver can gate X+ and bX+ per MAT strip (e.g., 48 transistors per stripe, contained in column decode area. The BLSAs can be enabled per MAT based on block address. The rotated addressed can enable different MATs per block. The local data line (LDL) to global data line (GDL) routing can be achieved using logic per MAT. The logic per MAT needs to select LDL from different MATs. The logic can disable unused connections within a MAT.

FIG. 8C illustrates SA control logic 814 according to at least one embodiment. The SA control logic 814 can disable BLSA blocks for MATs that are not used within a block. A portion of the address (e.g., AX[15:14]) can be a pre-coded one-hot bus) that is shifted across the MATs to only enable a subset of the BLSA blocks per block. The SA control logic 814 could be used, as one example, if MWLs across multiple blocks were enabled. It should be noted that the SA control logic 814 can be disable the BLSAs for a subset of MATs, which are not being accessed, within a block. The SWLs for the unaccessed MATs will also be disabled. The number of circuits in each SWL driver can be less since a set of MWLs across a group of blocks (not within a single block) is being enabled.

In at least one embodiment, the errors caused by a Rowhammer attack can be reduced to two MATs (e.g., 32 bits) or one MAT (e.g., 16 bits). Current on-die ECC memory can help detect and correct errors, but there could be a gap. For example, 16 bits can be corrected per 32 B for HBM and 1b correction per 16B for LPDDR5. The gap can be augmented by host ECC and/or DRAM changes, such as in-line ECC, DRAM metadata storage, on-die ECC improvements (e.g., HBM3 already includes 16-bits metadata per 32B payload).

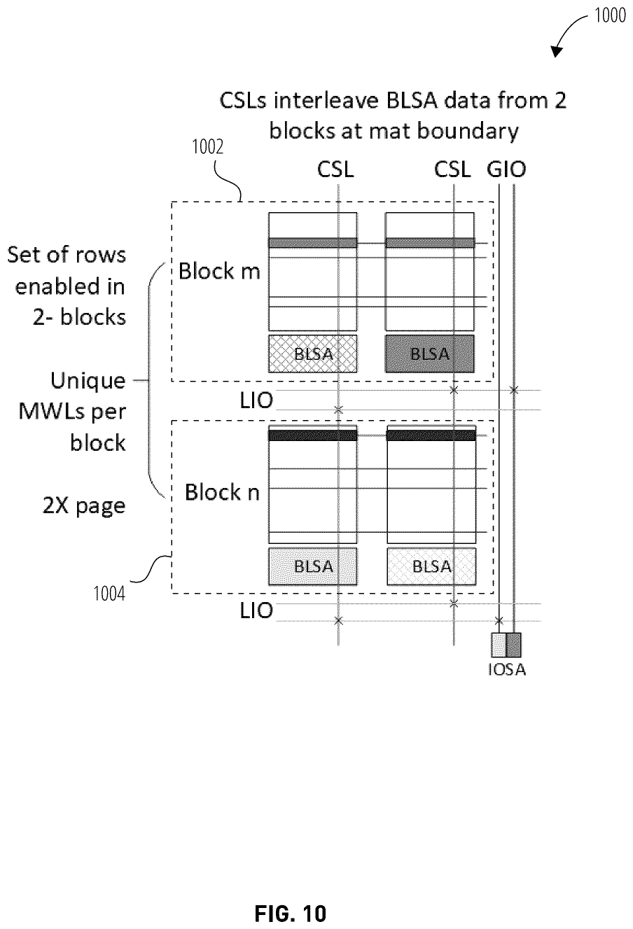

In at least one embodiment, the fault boundary can be reduced to one MAT (16 bits) with pages (row buffers) enabled in multiple blocks, for a larger aggregate page size (e.g., 2 KB across 2 blocks). It should be noted that multiple blocks are enabled (e.g., representing 2× page size), but only data from one page (e.g., 1K page size) is output on the IOSAs. In this case, the Rowhammer (RH) errors can be bound to one MAT, such as illustrated in FIG. 10. ECC memory and RAS mechanisms as described herein can be used to detect and correct errors that are caused by a Rowhammer attack. In another embodiment, the SWL logic can be changed so that it is not shared between two MATs.

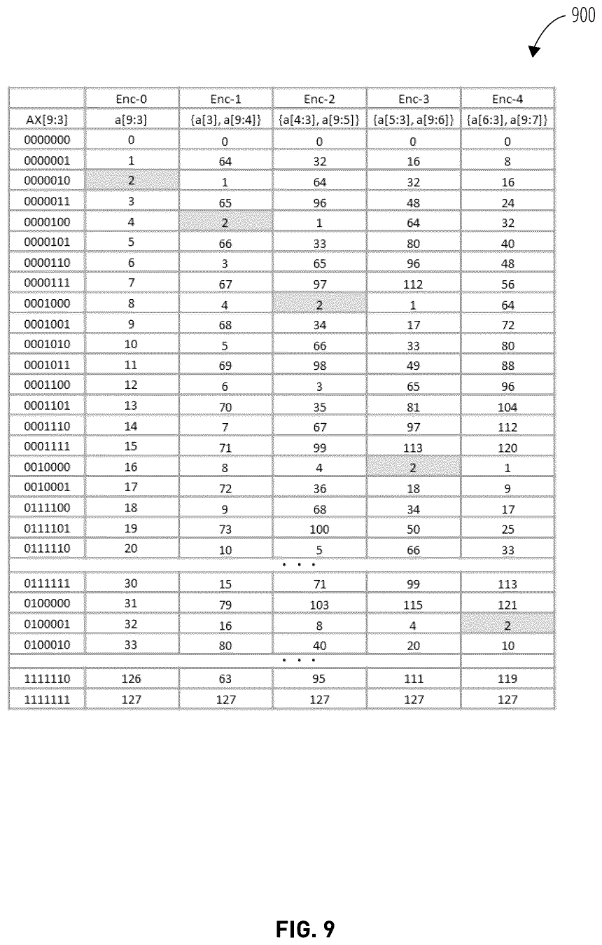

FIG. 9 is an encoding table 900 illustrating five unique encodings of unique MWL addresses across blocks and a simple shift down and rotate function to change adjacent rows for most MATs according to at least one embodiment. The encoding table 900 is similar to encoding table 500 except the MWLs are enabled across blocks. There can be unique MWL encoding per block with 7 unique encoding possible with AX[9:3]. The encoding table 900 only shows five of the 7 unique encodings. The MWL swizzling changes adjacent rows with a simple shift down and rotate 1-bit technique. The varying technique changes the encoded adjacent rows across the MATs in the different blocks. For example, the encoded adjacent rows for the third row (r2) vary across the different encodings. In particular, the encoded adjacent rows of a third row (r2) are rows (r1, r3) for a first encoding, rows (r65, r66) for a second encoding, rows (r97, r34) for a third encoding, rows (r113, r8) for a fourth encoding, and rows (r121, r10) for a fifth encoding. Although the varying technique illustrated in FIG. 9 is a simple shift down and rotate technique, in other embodiments, other varying techniques can be used to varying the MWLs across MATs and blocks according to unique encodings.

FIG. 10 is a block diagram of a portion of a memory bank 1000 with sets of rows enabled across blocks according to at least one embodiment. The portion of the memory bank 1000 includes a first block 1002 and a second block 1004, each having two MATs. The memory bank 1000 can include more blocks and the blocks can include more MATs. A set of rows can be enabled in two blocks. Since rows are enabled in two blocks, the pages size will be doubled (2× page size). Selecting the set of MWLs in two blocks can reduce the fault boundary to one MAT (16 bits), but CSLs will select data from one page (e.g. 1 KB), with this page split across blocks. In this embodiment, the MWLs are unique per block, and the CSLs interleave BLSA data from two blocks at a MAT boundary. It should be noted that in FIG. 10 the BLSAs are not disabled, Instead, the CSLs are used to move data from a subset of the BLSAs to the IOSAs.

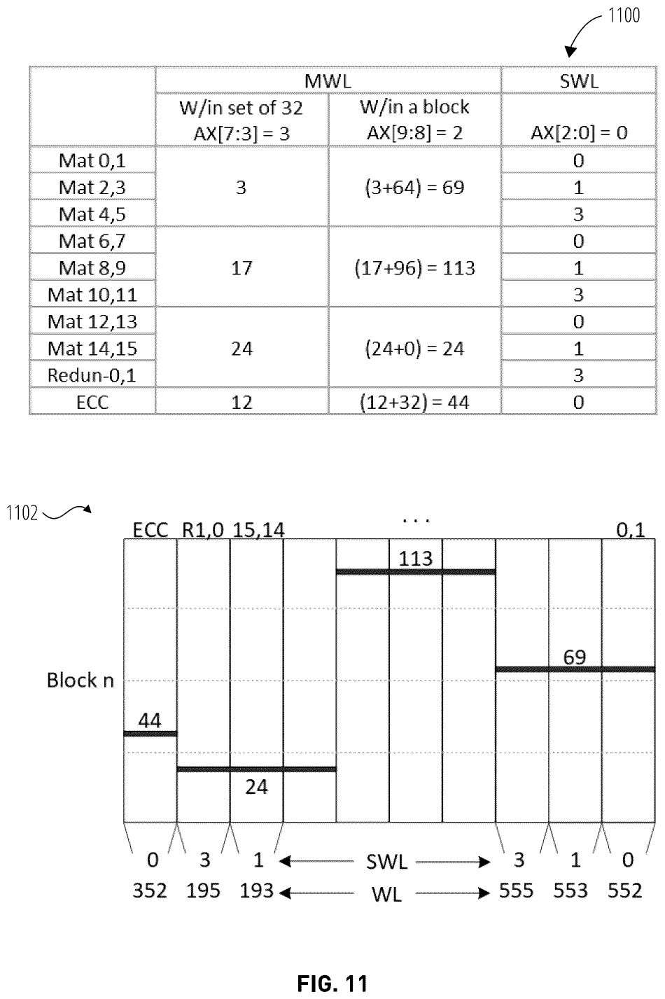

As described herein, the SWL encoding can also vary across the SWLs per each MWL, as illustrated in FIG. 11.

FIG. 11 illustrates decoding different SWL encodings every two MATs within a block according to at least one embodiment. In this embodiment, the address portions can be as follows: AX[9:8]=2, AX[7:3]=3, AX[2:0]=0. As illustrated in an encoding table 1100 of FIG. 11, there are different SWL encoding every two MATs. There are four MWL encodings (e.g., 3, 17, 24, 12 based on the prior encoding table 500), and there are three SWL encodings per MWL (e.g., 0, 1, 3 based on the prior encoding table 700). The second and third portions of the address (e.g., AX[9:8]+AX[2:0]) can select the unique SWL. Both portions can be varied across the MATs. Additional redundant or metadata MATs can also be supported.

As illustrated in graph 1102, four different MWL can be enabled (3, 17, 24, 12) and three different SWLs (44, 24, 113, 69) can be selected across the MATs.

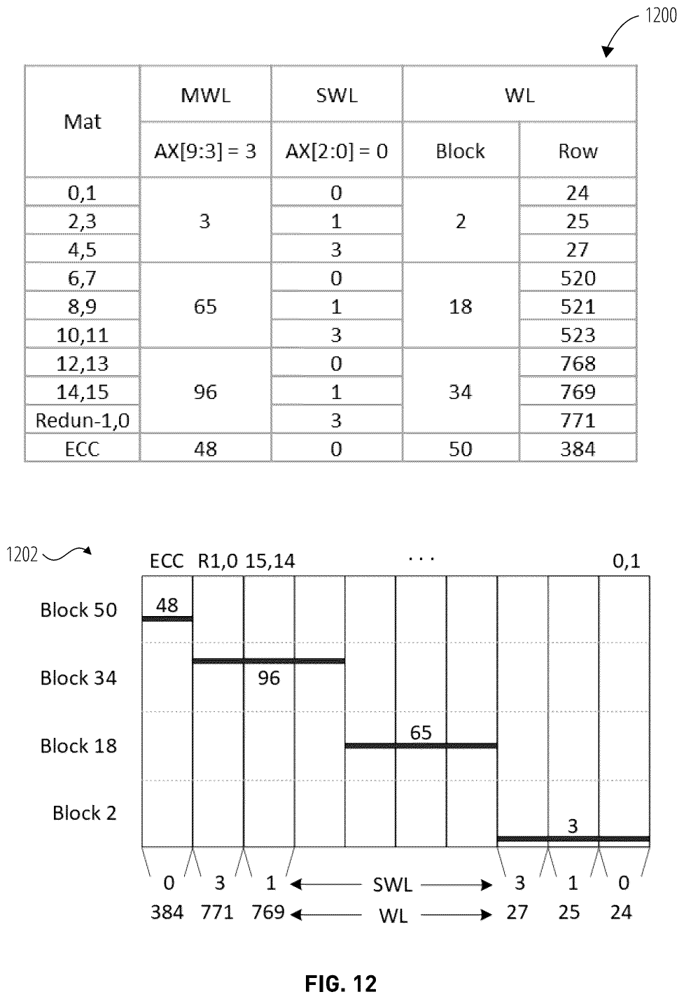

FIG. 12 illustrates decoding different SWL encodings every two MATs with multiple blocks according to at least one embodiment. In this embodiment, the address portions can be as follows: AX[15:10]=0x12, AX[9:3]=0x3, AX[2:0]=0x0. As illustrated in an encoding table 1200 of FIG. 12, there are different SWL encoding every two MATs. There are four MWL encodings (e.g., 3, 65, 96, 48 based on the prior encoding table 1000), and there are two SWL encodings per MWL (e.g., 0, 3 based on the prior encoding table). A portion of the address (e.g., AX[13:10]) can select four blocks (e.g., 2, 18, 34, 50 with AX[13:10]=0x2), and another portion (e.g., AX[15:14]) enables or disables the BLSA per MAT. It should be noted that the maximum encoding space is larger. Additional redundant or metadata MATs can also be supported.

As illustrated in graph 1202, four different MWL can be enabled (e.g., 3, 65, 96, 48), four blocks (2, 18, 34, 50) can be selected, and three different SWLs (0, 1, 3) can be selected across the MATs.

In at least one embodiment, the unique encodings can be configured per die. In some embodiments, fuses can be blown at assembly with no flexibility to reconfigure. In other embodiments, a programmable die identifier (ID) can be used, similar to DDR5 per-DRAM addressability. In at least one embodiment, the host can configure with mode register write (MRW) commands during initialization. In at least one embodiment, the unique encodings can be configured per MAT (or set of MATs) within the die. The decoder logic can be hard coded by the vendor. The address shifts/variations can be configured with variable MATs per encoding for more flexibility. Similarly, the host can configure with MRW commands during initialization. In some cases, a controller can be aware of the fault boundary to ensure optimal system-wide RAS. In some cases, the error detection logic is no longer siloed.

In at least one embodiment, the row address permutations across dies within a stack can be used. Row address decoding using row-address sent by the memory controller and permutation bits. The permutation bits can be different for each die to make different row-address mapping. The row-address mappings can be programmed through e-fuse (per-die, similar with Chip identifier (CID)), bonding option, hard-wired, or a random pattern generator. The row address permutations can be applied for both 3DS configurations and wire-bounded (WB) solutions. A similar approach can be used in 3DS configurations.

In some embodiments, complex CA coding schemes in LPDDRx can introduce additional challenges to swizzling external CA line directly. However, a primary die in the 3DS configuration can send row and column address to secondary dies after decoding. This can be the approach in multi-die package solutions. The row address swizzling using row address after command decoding.

As described herein, multiple local wordlines (SWLs) can be enabled to mitigate Rowhammer attacks. The same aggregate page size can be used using sub-array concepts, with multiple sub-pages being enabled. A single activate (ACT) command can enable multiple sub-pages simultaneously. The address mapping can be done to avoid Rowhammer errors. There are multiple options, including different MWLs selected across MATs, within the same block or across different blocks. Different SWLs can be enabled per MAT (or subset of MATs). Different rows across multiple dies (any number of dies in a 3DS configuration) can be enabled. Different combinations of these options can be used for Rowhammer mitigation. The decoding can be hard-coded or programmable. As described herein, the faults caused by a Rowhammer attack are bounded to one or two MATs (e.g., 16 bits or 32 bits, respectively), as described herein. In some cases, there can be 100% correction on HBM with on-die ECC and SWL drivers bounded to 16 bits. In at least one embodiment, a DRAM, for an activate command, can enable multiple intermediate MWLs and different SWLs are enabled from each MWL such that different SWLs in each MAT are varied (i.e., re-mapped). In at least one embodiment, an error detection mechanism can be used to detect failures. In some cases, the different SWL activations can be spread across different die in a stacked device, for example, for devices that access multiple die at the same time. The mechanisms described herein can be used for Rowhammer mitigation.

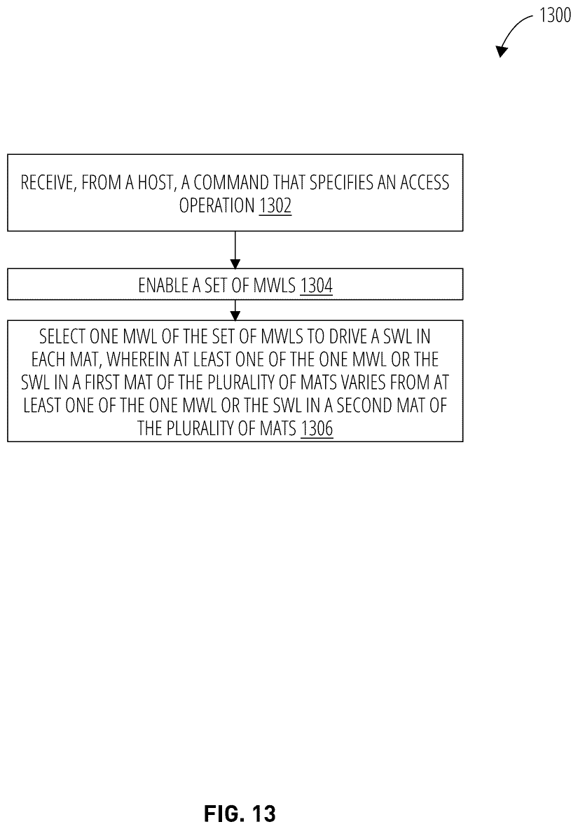

FIG. 13 is a flow diagram of a method 1300 for Rowhammer mitigation according to at least one embodiment. The method 1300 may be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 1300 is performed by decoding logic, such as command decode block 108, row decoder 112, column decoder 114, and column decoder 114 of FIG. 1. In at least one embodiment, the method 1300 is performed by decoder logic (e.g., row decoder 112 and column decoder 114) and SWL drivers 206 of FIG. 2.

Referring to FIG. 13, the method 1300 begins with the logic receives, from a controller, at a dynamic random-access memory (DRAM) device having a plurality of MATs, an access operation (block 1302). Each MAT includes a set of MWLs and a set of SWLs for each MWL. At block 1304, the logic, responsive to the access operation, enables a set of MWLs. At block 1306, the logic, responsive to the access operation, selects one MWL of the set of MWLs to drive a SWL in each MAT. At least one of the one MWL address or the SWL address in a first MAT of the plurality of MATs varies from at least one of the one MWL address or the SWL address in a second MAT of the plurality of MATs.

In a further embodiment, the logic detects an error using an error detection mechanism.

In a further embodiment, the access operation includes a physical row address. The logic translates the physical row address to a different SWL per MAT such that an aggressor row affects different victim rows across the plurality of MATs.

It is to be understood that the above description is intended to be illustrative, and not restrictive. Many other implementations will be apparent to those of skill in the art upon reading and understanding the above description. The scope of the disclosure should, therefore, be determined with reference to the appended claims, along with the full scope of equivalents to which such claims are entitled.

In the above description, numerous details are set forth. It will be apparent, however, to one skilled in the art, that the aspects of the present disclosure may be practiced without these specific details. In some instances, well-known structures and devices are shown in block diagram form, rather than in detail, in order to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “setting,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any procedure for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

It is to be understood that the above description is intended to be illustrative and not restrictive. Many other implementations will be apparent to those of skill in the art upon reading and understanding the above description. Therefore, the disclosure scope should be determined with reference to the appended claims, along with the full scope of equivalents to which such claims are entitled.

In the above description, numerous details are set forth. It will be apparent, however, to one skilled in the art that the aspects of the present disclosure may be practiced without these specific details. In some instances, well-known structures and devices are shown in block diagram form rather than in detail to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to the desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

However, it should be borne in mind that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “setting,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk, including floppy disks, optical disks, CD-ROMs, and magnetic-optical disks, read-only memories (ROMs), random access memories (RAMs), erasable programmable ROMs (EPROMs), electrically erasable programmable ROMs (EEPROMs), magnetic or optical cards, or any type of media suitable for storing electronic instructions, each coupled to a computer system bus.

The algorithms and displays presented herein are not inherently related to any particular computer or other apparatus. Various general-purpose systems may be used with programs in accordance with the teachings herein, or it may prove convenient to construct more specialized apparatuses to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any procedure for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

What is claimed is:

1. A dynamic random-access memory (DRAM) device comprising:
a command interface to receive an activate command; and
a plurality of memory array tiles (MATs), each MAT comprising multiple rows and columns of memory cells, wherein each MAT of the plurality of MATs having a plurality of main wordlines (MWLs) and a plurality of sub-wordlines (SWLs), wherein each row in the respective MAT corresponds to a SWL and each column in the respective MAT corresponds to a bitline (BL), wherein, for the activate command, a set of intermediate MWLs is enabled and different SWLs are activated for each MWL of the set of intermediate MWLs such that a different SWL address is selected in each MAT.

2. The DRAM device of claim 1, further comprising an error detection mechanism to detect failures in a portion of read data or write data corresponding to the plurality of MATs.

3. The DRAM device of claim 1, wherein the DRAM device comprises a single die.

4. The DRAM device of claim 1, wherein the DRAM device is a stacked device comprising multiple die, wherein the different SWLs activated are spread across different die in in the stacked device.

5. The DRAM device of claim 1, wherein the different SWLs in each MAT being varied is a Rowhammer mitigation mechanism that limits a number of bits per read flipped due to a Rowhammer attack.

6. The DRAM device of claim 1, wherein a physical row address, received from a controller, translates to a different SWL per MAT such that an aggressor row affects different victim rows across the plurality of MATs.

7. The DRAM device of claim 1, wherein the different SWLs in each MAT being varied limits a number of bits flipped per read operation due to one or more errors in one or two MATs of the plurality of MATs.

8. The DRAM device of claim 1, further comprising:
a row decoder to receive at least a first portion of an address associated with the activate command;
a column decoder to receive at least a second portion of the address; and
a memory bank coupled to the row decoder and the column decoder, wherein the memory bank comprises a plurality of blocks, wherein a first block of the plurality of blocks comprises:
the plurality of MATs;
SWL drivers; and
bitline sense amplifiers (BLSAs), wherein, in response to the activate command, the row decoder is to assert the set of intermediate MWLs in the first block, and the column decoder is to activate the different SWLs, one SWL per MAT or per MAT-pair, wherein the different SWLs in each MAT or MAT-pair are varied.

9. The DRAM device of claim 1, further comprising:
a memory bank comprising the plurality of MATs:
MWL drivers coupled to the plurality of MATs;
SWL drivers coupled to the plurality of MATs; and
sense amplifier (SA) control logic coupled to the plurality of MATs, wherein the MWL drivers to perform a first decode operation to enable a set of a number of MWLs, wherein the SA control logic and SWL drivers to perform a second decode operation to select one SWL per MAT.

10. The DRAM device of claim 9, wherein the plurality of MATs is located in a first block of a plurality of blocks of the memory bank.

11. The DRAM device of claim 9, wherein the plurality of MATs is located across multiple blocks of the memory bank.

12. The DRAM device of claim 9, further comprising command and address (CA) logic to encode each MAT of the plurality of MATs with a set of unique MWL addresses that vary across the plurality of MATs.

13. The DRAM device of claim 12, wherein the CA logic is to encode each MAT of the plurality of MATs with a set of unique SWL addresses that vary across the plurality of MATs.

14. The DRAM device of claim 8, further comprising command and address (CA) logic to:
encode a first MAT of the plurality of MATs with a first set of MWL addresses; and
encode a second MAT of the plurality of MATs with a second set of MWL address, the second set being different than the first set.

15. A memory die comprising:
one or more blocks having a plurality of memory array tiles (MATs), each MAT comprising a set of main wordlines (MWLs) and a set of sub-wordlines (SWLs) for each MWL;
decoding logic to receive an address associated with an access operation and decode the address in a first decode stage and a second decode stage, wherein the decoding logic is to:
in the first decode stage, enable a set of MWLs; and
in the second decode stage, select one MWL of the set of MWLs to drive a SWL in each MAT, wherein at least one of the one MWL or the SWL in a first MAT of the plurality of MATs varies from at least one of the one MWL or the SWL in a second MAT of the plurality of MATs.

16. The memory die of claim 15, wherein the plurality of MATs are part of a first block of the one or more blocks.

17. The memory die of claim 15, wherein the first MAT is part of a first block of the one or more blocks, and the second MAT is part of a second block of the one or more blocks.

18. The memory die of claim 15, wherein the first MAT has a first set of MWL addresses that vary from a second set of MWL addresses of the second MAT.

19. The memory die of claim 15, wherein the first MAT has a first set of SWL addresses that vary from a second set of SWL addresses of the second MAT.

20. A method of operation in a dynamic random-access memory (DRAM) device having a plurality of memory array tiles (MATs) wherein each MAT comprises a set of main wordlines (MWLs) and a set of sub-wordlines (SWLs) for each MWL, the method comprising:
receiving, from a controller, a command that specifies an access operation; and
responsive to the command that specifics the access operation,
enabling a set of MWLs; and
selecting one MWL of the set of MWLs to drive a SWL in each MAT, wherein at least one of the one MWL or the SWL in a first MAT of the plurality of MATs varies from at least one of the one MWL or the SWL in a second MAT of the plurality of MATs.
